(19) United States
(12) Patent Application Publication
(10) Pub. No.: US 2003/0134463 A1
(43) Pub. Date: Jul. 17, 2003

(54) Method for fabricating a high voltage device

(76) Inventors: Mu-Yi Liu, Taichung (TW); Tso-Hung Fan, Taipei Hsien (TW); Yen-Hung Yeh, Taoyuan Hsien (TW); Kwang-Yang Chan, Hsinchu (TW); Tao-Cheng Lu, Kaoshiung (TW)

Correspondence Address: J.C. Patents, Inc., Suite 250, 4 Venture, Irvine, CA, 92618, US

(21) Appl. No.: 10/058,673

(22) Filed: Jan. 28, 2002

(30) Foreign Application Priority Data
Jan. 16, 2002 (TW) 91100557

(51) Int. Cl. H01L 21/336

(52) U.S. Cl. 438/197

(57) ABSTRACT

A fabrication method for a high voltage device is described. A substrate is provided, wherein a gate structure of a high voltage device is already formed on the substrate. Thereafter, a first thermal process is conducted to form a first doped region in the substrate beside the gate structure of the high voltage device. A spacer is formed on the side of the gate structure of the high voltage device. An oxide layer is further formed on the gate structure of the high voltage device and on the surface of the first doped region. After this, a second thermal process is performed to form a second doped region in the substrate beside the side of the spacer.

### CROSS-REFERENCE TO RELATED APPLICATION

This application claims the priority benefit of Taiwan application serial no. 91100557, filed on Jan. 16, 2002.

### BACKGROUNDING OF THE INVENTION

1. Field of Invention

The present invention relates to a fabrication method for a semiconductor device. More particularly, the present invention relates to a fabrication method for a high voltage device.

2. Description of Related Art

A high voltage device is a device that can sustain a higher voltage that is applied to the device. In other words, the breakdown voltage of a high voltage device is higher than a regular device. In general, a more favorable high voltage device has a higher breakdown voltage. A high voltage device is normally formed along a regular device on a same wafer. A typical high voltage device comprises a gate, a source/drain region and a lightly doped drain region (LDD), wherein the LDD of the high voltage device encloses the source/drain region.

FIGS. 1A to 1D illustrate the process flow of fabricating a conventional high voltage device in a cross-sectional view.

As shown in FIG. 1A, the fabrication method for a conventional high voltage device comprises providing a substrate 100, the substrate 100 comprises a regular device region 102 and a high voltage device region 104. Gate structures 110, 116 are respectively formed in the regular device region 102 and the high voltage device region 104, wherein the gate structures 110, 116 comprise a polysilicon type of gate conductive layer 106, 112 and a gate oxide layer 108, 114.

Thereafter, lightly doped drain regions (LDD) 118, 120 are formed in the substrate 100 beside the sides of the gate structures 110, 116, respectively.

Continue to FIG. 1B, a first thermal process is conducted. The first thermal process is an annealing process performed on the lightly doped drain regions 118, 120.

Referring to FIG. 1C, spacers 117, 119 are formed on the sides of the gate structures 110, 116. Source/drain regions 122, 124 are then formed in the substrate 100 beside the sides of the spacers 117, 119 respectively, wherein the lightly doped drain region 120 in the high voltage device region 104 encloses the source/drain regions 124.

After this, as shown in FIG. 1D, a second thermal process is conducted. The second thermal process is an annealing process performed on the source/drain regions 122, 124. Accordingly, a regular device and a high voltage device are formed in the regular device region 102 and a high voltage device region 104, respectively.

In the conventional fabrication method for a high voltage device, the annealing of the lightly doped drain region in the high voltage device region and the annealing of the lightly doped drain region in the regular device region are concurrently conducted. Similarly, the annealing of the source/drain region in the high voltage device region and the annealing of the source/drain region in the regular device region are concurrently conducted. However, concurrently performing the annealing processes in both the regular device region and the high voltage device region, the dopant concentration in the lightly doped drain region of the high voltage device would be affected (increased) by the diffusion of dopants in the source/drain region. Accordingly, the breakdown voltage of the high voltage device can not be effectively increased.

### SUMMARY OF THE INVENTION

The present invention provides a fabrication method for a high voltage device, wherein the breakdown voltage of the high voltage device is increased.

The present invention provides a fabrication method for a high voltage device, wherein the dopants in the source/drain region are prevented from diffusing to the lightly doped drain region.

The present invention provides a fabrication method for a high voltage device, the method provides a substrate, wherein the substrate comprises a regular device region and a high voltage device region. A gate structure of a regular device and a gate structure of a high voltage device are respectively formed in the substrate of the regular device region and of the high voltage device region. Thereafter, a first lightly doped drain region is formed in the substrate beside the gate structure of the regular device. A first thermal process is then conducted, wherein the first thermal process includes performing an annealing process on the first lightly doped drain region. Subsequent to the first thermal process, a second lightly doped drain region is formed in the substrate beside the side of the gate structure of the high voltage device, wherein the second lightly doped drain region is formed by tilt ion implantation. A first spacer is further formed on the side of the gate structure of the regular device and a second spacer is formed on the side of the gate structure of the high voltage device. After this, an oxide layer is formed on the exposed surfaces of the substrate and the gate conductive layer to prevent the exposed surfaces from being damaged in the subsequent ion implantation process. A first source/drain region is formed in the substrate beside the first spacer, followed by performing the second thermal process, wherein the second thermal process includes an annealing conducted on the first source/drain region. Subsequent to the second thermal process, ion implantation is conducted in the substrate beside the second spacer to form a second source/drain region.

According to the fabrication method for a high voltage device of the present invention, the lightly doped drain region of the high voltage device is formed subsequent to the annealing of the lightly doped drain region of the regular device. Since the lattice defects generated in the ion implantation process are not repaired, the dopants in the lightly doped drain region of the high voltage device can diffuse along the interstitial in the low-temperature and long-time spacer forming process, the gradient of the ion concentration can be reduced, which in turns increases the breakdown voltage of the high voltage device.

The source/drain region of the high voltage device, in accordance to the present invention, is formed after the annealing of the source/drain region of a regular device. The dopants in the source/drain region are thus prevented from diffusing to the lightly doped drain region. Since the dopant concentration in the lightly doped drain region maintains unchanged, the breakdown voltage of the high voltage device is thus effectively increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A to 1D illustrate a process flow of fabricating a high voltage device according to the prior art in a cross-sectional view; and

FIGS. 2A to 2E illustrate a process flow of fabricating a high voltage device according to one aspect of the present invention in a cross-sectional view.

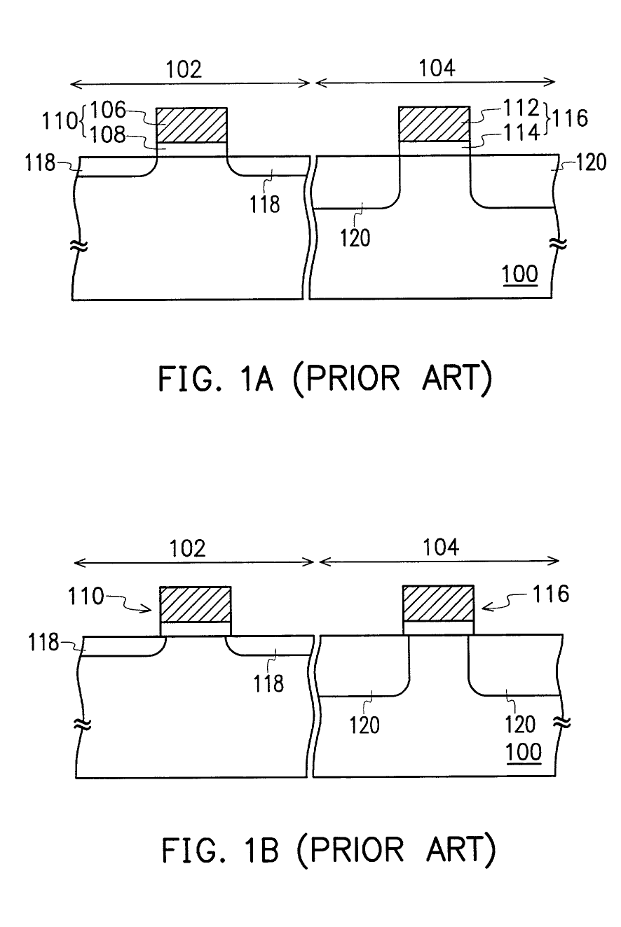

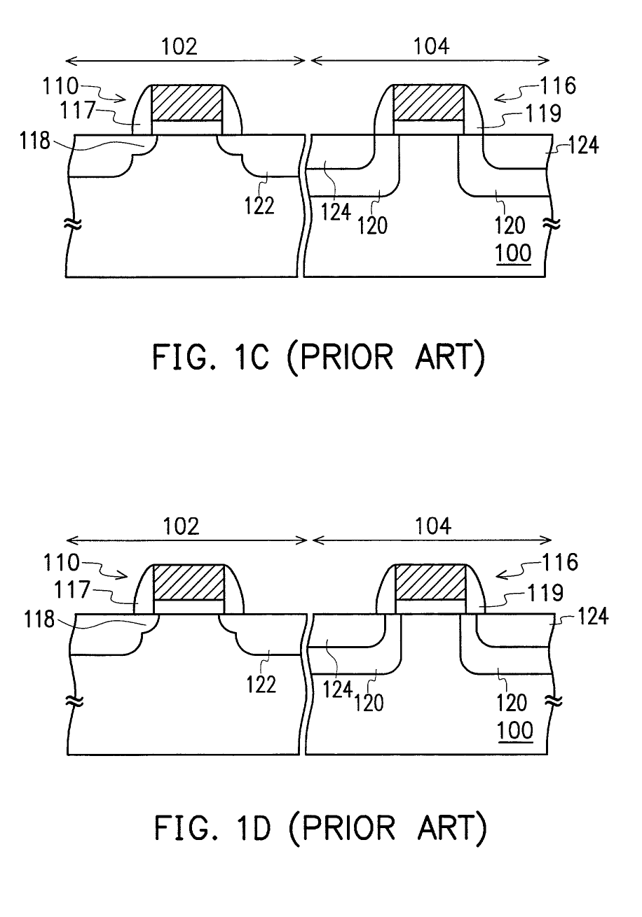

### DESCRIPTION OF THE PREFERRED EMBODIMENTS

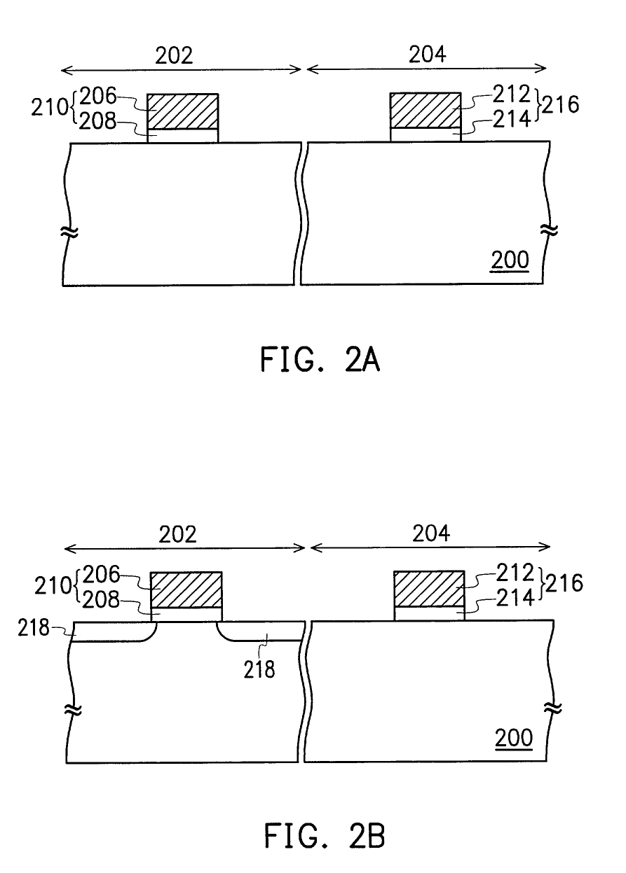

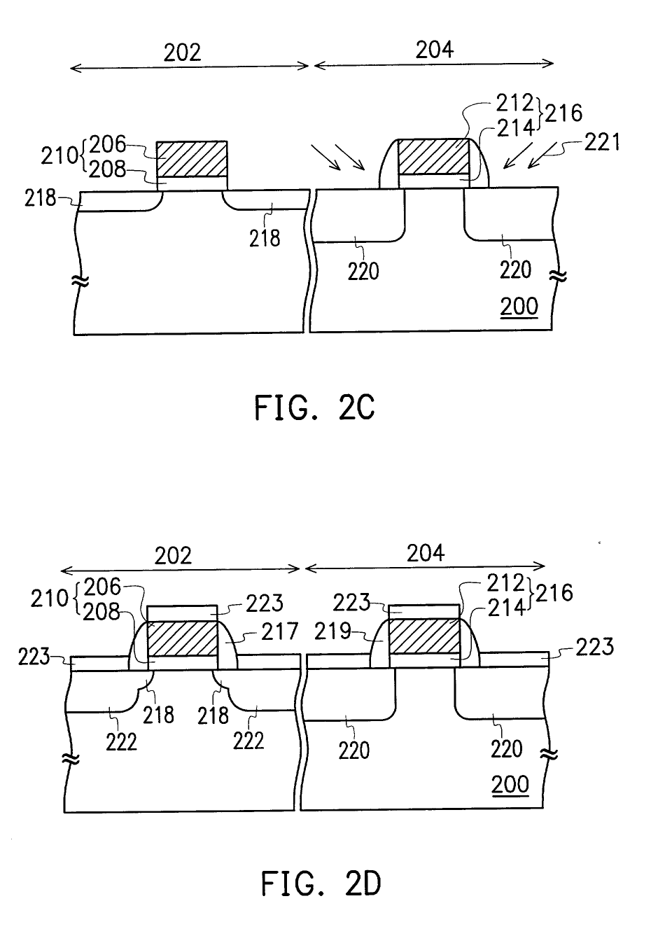

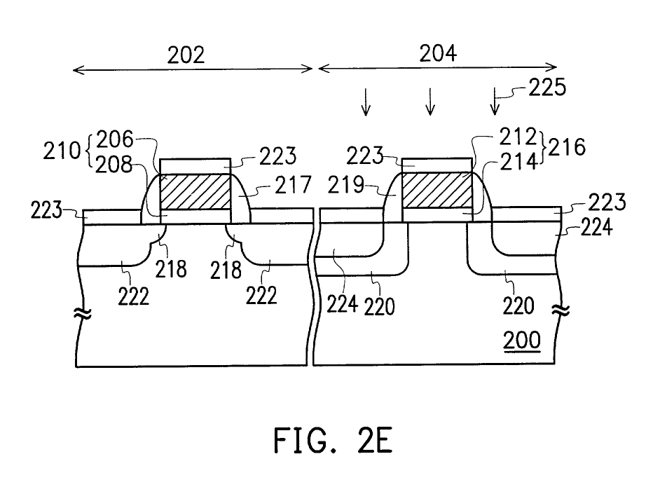

FIGS. 2A to 2E illustrate a process flow of fabricating a high voltage device according to one aspect of the present invention in a cross-sectional view.

As shown in FIG. 2A, a substrate 200 is provided, wherein the substrate 200 comprises a regular device region 202 and a high voltage device region 204. Gate structures 210, 216 are then formed on the regular device region 202 and the high voltage device region 204, respectively, wherein each gate structures 210, 216 comprises a gate conductive layer 206, 212, and a gate oxide layer 208, 214. The gate conductive layers 206, 212 include polysilicon.

Thereafter, as shown in FIG. 2B, a lightly doped drain region 218 is formed in the substrate 200 of the regular device region 202 beside the side of the gate structure 210. Thereafter, a first thermal process is conducted. The first thermal process includes an annealing conducted on the lightly doped drain region 218, wherein the first thermal process is conducted at a temperature of about 1000 degrees Celsius for about 30 seconds.

Referring to FIG. 2C, a lightly doped drain region 220 is formed in the substrate 200 of the high voltage device region 204 beside the side of the gate structure 216. Forming the lightly doped drain region 220 includes performing a tilt ion implantation process 221, wherein the tilt ion implantation process 221 is conducted with a power of about 100 KeV. The implanted ions include boron and the ion concentration is about 5×10¹³/cm². Moreover, the tilt ion implantation process 221 is conducted at a tilted angle of about 45 degrees.

Thereafter, as shown in FIG. 2D, spacers 217, 219 are respectively formed on the sides of the gate structures 210, 216, wherein the spacers 217, 219 are formed by forming a conformal dielectric layer (not shown in Figure) on the substrate 200, followed by dry etching the conformal dielectric layer. Forming the conformal dielectric layer includes performing a deposition process for about 113 minutes at about 630 degrees Celsius.

Thereafter, an oxide layer 223 is formed on the exposed substrate 200 surface and the gate conductive layers 206, 212 to prevent the surfaces of the substrate 200 and the gate conductive layers 206, 212 from being damaged in the subsequent ion implantation process. The oxide layer 223 is formed by, for example, thermal oxidation.

Thereafter, source/drain regions 222 are formed in the substrate 200 beside the spacer 217 of the gate structure 210 in the regular device region 202. A second thermal process is further conducted. The second thermal process includes performing an annealing on the source/drain regions 222, wherein the second thermal process is conducted at about 1000 degrees Celsius for about 30 seconds. The manufacturing for a regular device region 202 is thereby completed.

Referring to FIG. 2E, a source/drain region 224 is formed in the substrate 200 beside the spacer 219 of the gate structure 216 in the high voltage region 204. The source/drain region 224 is enclosed by the lightly doped drain region 220. The source/drain region 224 is formed by performing an ion implantation process at a power of about 50 KeV. The implanted ions include boron at a concentration of about 5×10¹⁵ l/cm². After this, the manufacturing of a high voltage device is completed.

The manufacturing of the lightly doped drain region 220 of the high voltage device is subsequent to the annealing process for the lightly doped drain region 218 of the regular device is completed. Therefore, the lattice defects formed during the ion implantation process 221 in forming the lightly doped drain region 220 are not repaired. The ions in the lightly doped drain region 220 can thereby diffuse along the interstitial to the bottom of the substrate 200, to reduce the gradient of the dopant concentration in the lightly doped drain region 220, which in turns, increases the breakdown voltage of the high voltage device.

Additionally, the source/drain region 224 of the high voltage device is formed after the annealing process for the source/drain region 222 of the regular device is completed. The ions in the source/drain region 224 of the high voltage device are prevented from diffusing to the lightly doped drain region 220 due to the high temperature of the annealing process. As a result, the ion concentration in the light doped drain region 220 is prevented from varying to increase the breakdown voltage of the high voltage device.

In accordance to the manufacturing method of a high voltage device of the present invention, the lightly doped drain region of the high voltage device is formed after the annealing process for the lightly doped drain region of the regular device. Since the lattice defects generated in the ion implantation process are not repaired, ions in the lightly doped drain region of the high voltage device will diffuse along the interstitial to reduce the gradient of the ion concentration and to effectively increase the breakdown voltage of the high voltage device.

Moreover, the source/drain region of the high voltage device is formed after the annealing process for the source/drain region of the regular device is completed. The ions in the source/drain region of the high voltage device are prevented from diffusing to the lightly doped drain region to effectively increase the breakdown voltage.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fabrication method for a high voltage device, comprising:
providing a substrate, wherein a gate structure of a high voltage device is already formed on the substrate;
performing a first thermal process;
forming a first doped region in the substrate beside a side of the gate structure of the high voltage device subsequent to the first thermal process;
forming a spacer on the side of the gate structure of the high voltage device;
forming an oxide layer on the gate structure of the high voltage device and a surface of the first doped region;
performing a second thermal process; and
forming a second doped region in the substrate beside the spacer subsequent to the second thermal process.

2. The method of claim 1, wherein the first doped region includes a lightly doped drain region.

3. The method of claim 1, wherein the first doped region is formed by a tilt ion implantation process.

4. The method of claim 3, wherein the tilt ion implantation process is conducted with a power of about 100 KeV, at a dopant concentration of about 5×10¹³/cm² and at a tilt angle of about 45 degrees.

5. The method of claim 1, wherein the second doped region includes a source/drain region.

6. The method of claim 1, wherein the second doped region is formed by an ion implantation process.

7. The method of claim 6, wherein the ion implantation process is conducted with a power of about 50 KeV and at dopant concentration of about 5×10¹⁵/cm².

8. The method of claim 1, wherein the first thermal process is conducted at about 1000 degrees Celsius.

9. The method of claim 1, wherein the first thermal process is conducted at about 30 seconds.

10. The method of claim 1, wherein the second thermal process is conducted at about 1000 degrees Celsius.

11. The method of claim 10, wherein the second thermal process is conducted form about 30 seconds.

12. A fabrication method f or a high voltage device, comprising:
providing a substrate, the substrate already comprises a gate structure of a regular device and a gate structure of a high voltage device;
forming a first lightly doped drain region in the substrate beside a side of the gate structure of the regular device;
performing a first thermal process;
forming a second lightly doped drain region in the substrate beside a side of the gate structure of the high voltage device;
forming a first spacer on a side of the gate structure of the regular device and forming a second spacer on the side of the gate structure of the high voltage device;
forming a first source/drain region in the substrate beside the side of the first spacer;
performing a second thermal process; and
forming a second source/drain region in the substrate beside the side of the second spacer subsequent to the second thermal process.

13. The method of claim 12, wherein the first doped region is formed by a tilt ion implantation process.

14. The method of claim 13, wherein the tilt ion implantation process is conducted with a power of about 100 KeV, at a dopant concentration of about 5×10³/cm² and at tilt angle of about 45 degrees.

15. The method of claim 12, wherein the second doped region is formed by an ion implantation process.

16. The method of claim 15, wherein the ion implantation process is conducted with a power of about 50 KeV and at a dopant concentration of about 5×10¹⁵/cm².

17. The method of claim 12, wherein the first thermal process is conducted at about 1000 degrees Celsius.

18. The method of claim 17, wherein the first thermal process is conducted for about 30 seconds

19. The method of claim 12, wherein the second thermal process is conducted at about 1000 degrees Celsius.

20. The method of claim 19, wherein the second thermal process is conducted for about 30 seconds.
